(19) United States
(12) Patent Application Publication
(10) Pub. No.: US 2014/0084268 A1
(43) Pub. Date: Mar. 27, 2014

(54) METHOD OF FORMING POLYSILICON FILM, THIN FILM TRANSISTOR AND DISPLAY DEVICE INCLUDING POLYSILICON FILM

(71) Applicants: Yong-Duck SON, Yongin-City (KR); Ki-Yong LEE, Yongin-City (KR); Jin-Wook SEO, Yongin-City (KR); Min-Jae JEONG, Yongin-City (KR); Tak-Young LEE, Yongin-City (KR)

(72) Inventors: Yong-Duck SON, Yongin-City (KR); Ki-Yong LEE, Yongin-City (KR); Jin-Wook SEO, Yongin-City (KR); Min-Jae JEONG, Yongin-City (KR); Tak-Young LEE, Yongin-City (KR)

(21) Appl. No.: 13/962,105

(22) Filed: Aug. 8, 2013

(30) Foreign Application Priority Data
Sep. 25, 2012 (KR) 10-2012-0106640

(51) Int. Cl. H01L 29/786; H01L 51/52; H01L 21/02

(52) U.S. Cl. CPC H01L 29/78672; H01L 21/02532; H01L 51/52
USPC 257/40; 438/486; 257/66; 257/72

(57) ABSTRACT

A method of forming a polysilicon film includes: forming an amorphous silicon film on a substrate; adsorbing a metal catalyst on the amorphous silicon film, crystallizing the amorphous silicon film through heat treatment to form the polysilicon film, the polysilicon film including a grain internal region and a grain boundary where the metal catalyst remains, providing an etchant having different oxidation selectivities with respect to the grain internal region and the grain boundary, and etching a surface of the polysilicon film by the etchant to remove the metal catalyst remaining on the grain boundary.

### CROSS-REFERENCE TO RELATED APPLICATION

This application claims priority under 35 U.S.C. §119 to Korean Patent Application No. 10-2012-0106640 filed in the Korean Intellectual Property Office on Sep. 25, 2012, and entitled: “METHOD OF FORMING POLYSILICON FILM, THIN FILM TRANSISTOR AND DISPLAY DEVICE INCLUDING POLYSILICON FILM,” the entire contents of which are incorporated herein by reference.

### BACKGROUND

1. Field

Embodiments relate to a method of forming a polysilicon film, and a thin film transistor and a display device including the polysilicon film.

2. Description of the Related Art

A flat panel type display device, such as an organic light emitting diode (OLED) display or a liquid crystal display (LCD), may use a thin film transistor (TFT) as a driving element. In particular, a low temperature polysilicon thin film transistor (LTPS TFT) has excellent carrier mobility, and thus has been extensively used.

The low temperature polysilicon thin film transistor may include a polysilicon film formed by crystallizing an amorphous silicon film as an active layer.

### SUMMARY

Embodiments relate to a method of forming a polysilicon film including forming an amorphous silicon film on a substrate, adsorbing a metal catalyst onto the amorphous silicon film, crystallizing the amorphous silicon film through a heat treatment process to form a polysilicon film that includes a grain internal region and a grain boundary where the metal catalyst remains, providing an etchant having different oxidation selectivities with respect to the grain internal region and the grain boundary, and etching a surface of the polysilicon film by the etchant to remove the metal catalyst remaining on the grain boundary.

The metal catalyst may include nickel. The nickel may form nickel-silicide to act as a seed to perform crystallization during the heat treatment process

The etchant may include an oxidizing agent having a higher oxidizing speed with respect to the grain boundary than with respect to t the grain internal region.

The etchant may include potassium dichromate as the oxidizing agent and hydrofluoric acid as an agent to remove silicon oxide.

An etching thickness of the grain boundary may be greater than an etching thickness of the grain internal region in the polysilicon film.

Etching the surface of the polysilicon film by the etchant to remove the metal catalyst remaining on the grain boundary may form a recess portion that remains on a surface of the grain boundary after the metal catalyst is removed.

Embodiments are also directed to a thin film transistor including a polysilicon film formed according to the method described above, a gate insulating layer on the polysilicon film, a gate electrode on the gate insulating layer and overlapping the polysilicon film, and a source electrode and a drain electrode spaced apart from the gate electrode and electrically connected to the polysilicon film.

Embodiments are also directed to a thin film transistor, including a polysilicon film including a grain internal region and a grain boundary, the grain boundary including a recess portion corresponding to a position from which a metal catalyst was removed, a gate insulating layer on the polysilicon film, a gate electrode on the gate insulating layer and overlapping the polysilicon film, and a source electrode and a drain electrode spaced apart from the gate electrode and electrically connected to the polysilicon film.

Embodiments are also directed to a display device including a polysilicon film formed according to the method described above, a gate insulating layer on the polysilicon film, a gate electrode on the gate insulating layer and overlapping the polysilicon film, and a source electrode and a drain electrode spaced apart from the gate electrode and electrically connected to the polysilicon film.

The display device may further include a pixel electrode electrically connected to the drain electrode, a common electrode facing the pixel electrode, and an organic emission layer between the pixel electrode and the common electrode.

According to an embodiment, there is provided a display device including a polysilicon film including a grain internal region and a grain boundary, the grain boundary including a recess portion corresponding to a position from which a metal catalyst was removed, a gate insulating layer on the polysilicon film, a gate electrode on the gate insulating layer and overlapping the polysilicon film, and a source electrode and a drain electrode spaced apart from the gate electrode and electrically connected to the polysilicon film.

The display device may further include a pixel electrode electrically connected to the drain electrode, a common electrode facing the pixel electrode, and an organic emission layer between the pixel electrode and the common electrode.

### BRIEF DESCRIPTION OF THE DRAWINGS

Features will become apparent to those of ordinary skill in the art by describing in detail exemplary embodiments with reference to the attached drawings in which:

FIGS. 1A to 1H are schematic diagrams sequentially showing stages of a method of forming a polysilicon film according to an exemplary embodiment.

FIG. 2 is a microscopic image showing a surface of the polysilicon film formed by the method of the exemplary embodiment.

FIG. 3 is a scanning electron microscopic image showing an enlarged surface of a grain boundary shown in FIG. 2.

FIG. 4 is a cross-sectional view showing a thin film transistor according to the exemplary embodiment.

FIG. 5 is a cross-sectional view showing a display device according to the exemplary embodiment.

### DETAILED DESCRIPTION

Embodiments will be described more fully hereinafter with reference to the accompanying drawings, in which exemplary embodiments are shown. As those skilled in the art would realize, the described embodiments may be modified in various different ways, all without departing from the spirit or scope thereof.

In the drawings, the thickness of layers, films, panels, regions, etc., are exaggerated for clarity, and like reference numerals designate like elements throughout the specification. It will be understood that when an element such as a layer, film, region, or substrate is referred to as being “on” another element, it can be directly on the other element or intervening elements may also be present. In contrast, when an element is referred to as being “directly on” another element, there are no intervening elements present.

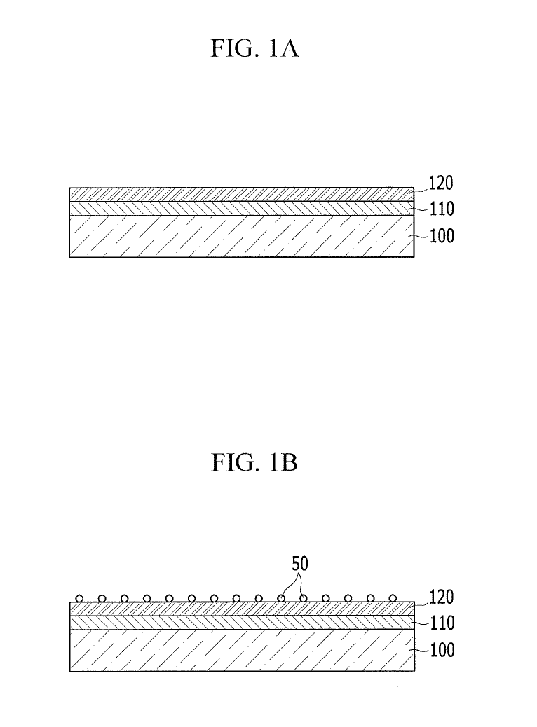

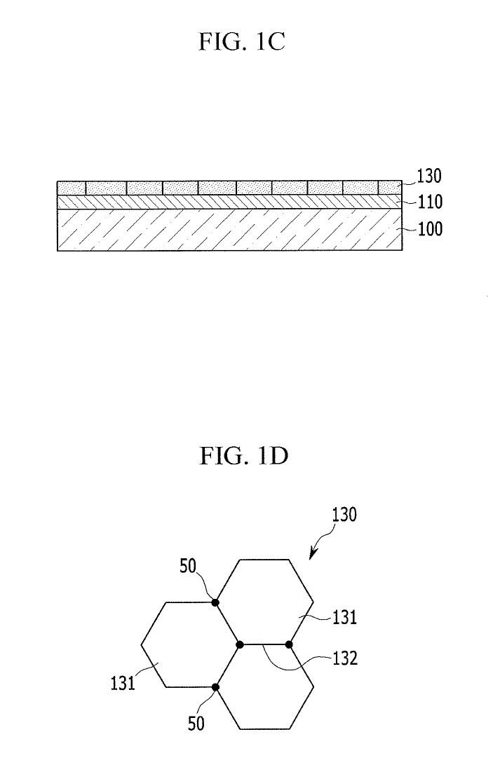

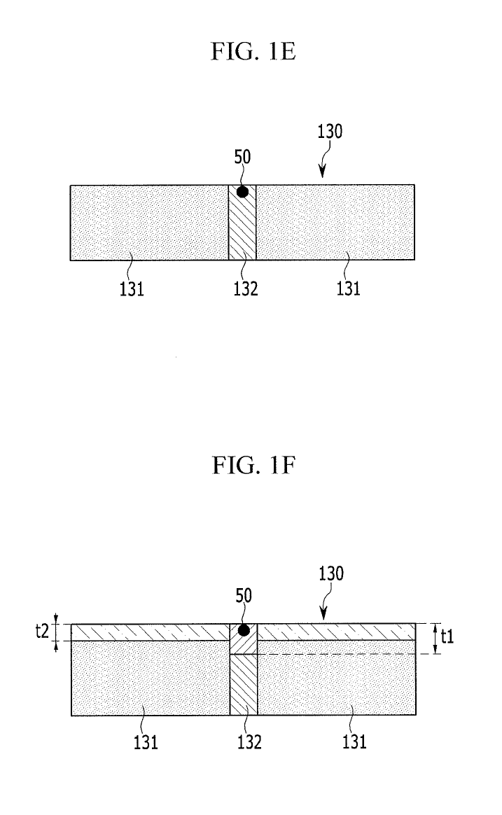

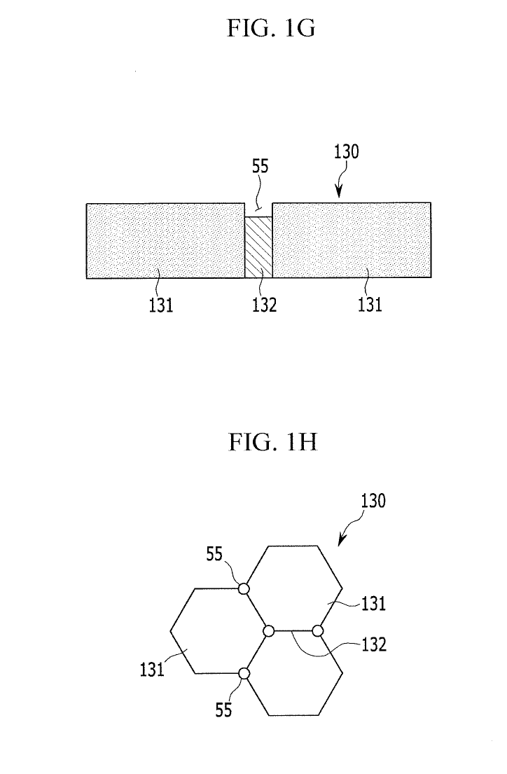

FIGS. 1A to 1H are schematic diagrams sequentially showing stages of a method of forming a polysilicon film according to an exemplary embodiment.

Referring to FIG. 1A, a buffer layer 110 is formed on a substrate 100. The substrate 100 may be manufactured by various materials such as glass, quartz, ceramics, plastics, and metal.

The buffer layer 110 is formed of a single film structure of silicon nitride (SiNₓ) or a double film structure where silicon nitride (SiNₓ) and silicon oxide (SiO₂) are laminated. The buffer layer 110 functions to prevent an unnecessary component such as an impurity element or moisture from being transmitted into an upper layer and to planarize a surface thereof. The buffer layer 110 may be omitted according to the type of substrate 100 and process conditions used.

Subsequently, an amorphous silicon film 120 is formed on the buffer layer 110.

The amorphous silicon film 120 may be formed by, for example, a chemical vapor deposition (CVD) method using a silane gas.

Referring to FIG. 1B, a metal catalyst 50 is adsorbed onto the amorphous silicon film 120. The adsorption of the metal catalyst 50 may be performed by a method such as ion doping, deposition, sputtering, coating, or implantation. The metal catalyst 50 may be adsorbed, for example, in a small dose in the range of 1×10¹⁰ atoms/cm² to 1×10¹⁴ atoms/cm².

The metal catalyst 50 may be selected from, for example, nickel (Ni), silver (Ag), gold (Au), copper (Cu), aluminum (Al), tin (Sn), cadmium (Cd), palladium (Pd), and an alloy or a combination thereof.

Subsequently, the amorphous silicon film 120 is subjected to a heat treatment process. The metal catalyst 50 adsorbed on the amorphous silicon film 120 acts as a seed during the heat treatment to grow a crystal therefrom, and as a result, as shown in FIG. 1C, a polysilicon film 130 is formed.

In the case where nickel (Ni) is used as the metal catalyst to crystallize the amorphous silicon film 120, nickel is reacted with silicon of the amorphous silicon film 120 to form nickel-silicide (NiSiₓ; x=0.5-2), and nickel-silicide acts as the seed to grow the crystal therearound.

In the crystallization method using the metal catalyst 50, the amorphous silicon film 120 may be rapidly crystallized at relatively low temperatures. In the polysilicon film 130 crystallized by using the metal catalyst 50, a grain having a size of tens to several tens micrometers (μm) is formed, and in this case, the metal catalyst 50 remains on the grain boundary.

FIG. 1D is a schematic diagram showing a flat surface of the polysilicon film shown in FIG. 1C, and FIG. 1E is an enlarged cross-sectional view of the polysilicon film shown in FIG. 1C.

In FIGS. 1D and 1E, the polysilicon film 130 is divided into a grain internal region 131 and a grain boundary 132. The metal catalyst 50, for example, nickel, remains on the grain boundary 132. The metal catalyst 50, if allowed to remain on the grain boundary 132, could act as a defect to increase a leakage current of a thin film transistor formed from the polysilicon film. Accordingly, it is desirable that the metal catalyst 50 be removed.

Referring to FIG. 1F, an etchant having different oxidizing selectivities with respect to the grain internal region 131 and the grain boundary 132 is prepared. The surface of the polysilicon film 130 is etched by using the etchant.

The etchant may be formed of a mixed solution of hydrofluoric acid (HF) and potassium dichromate (K₂Cr₂O₇). An oxidizing speed of potassium dichromate of the etchant, as a silicon oxidizing agent, is higher with respect to the grain boundary 132 than with respect to the grain internal region 131. In addition, the hydrofluoric acid functions to remove silicon oxides produced by the oxidizing of the polysilicon by the potassium dichromate.

If the polysilicon film 130 is subjected to the surface treatment by the etchant, an oxidizing thickness t1 of the grain boundary 132 is larger than an oxidizing thickness t2 of the grain internal region. In this case, the oxidizing thickness t1 of the grain boundary 132 is greater than the size of the metal catalyst 50. In addition, the hydrofluoric acid component of the etchant removes the oxidized portion of the grain boundary 132 and the grain internal region 131 to form the polysilicon film 130 from which the metal catalyst 50 has been removed.

FIG. 1G is an enlarged cross-sectional view of the polysilicon film from which the metal catalyst has been removed, and FIG. 1H is a schematic diagram showing a flat surface of the polysilicon film shown in FIG. 1G.

Referring to FIGS. 1G and 1H, the etching thickness of the grain boundary 132 in the polysilicon film 130 due to the aforementioned etchant is greater than the etching thickness of the grain internal region 131. Accordingly, in the polysilicon film 130, a height of an upper surface of the grain boundary 132 from which the metal catalyst has been removed is smaller than the height of the upper surface of the grain internal region 131.

In FIGS. 1G and 1H, reference numeral 55 shows a recess portion remaining after the metal catalyst has been removed from the surface of the grain boundary.

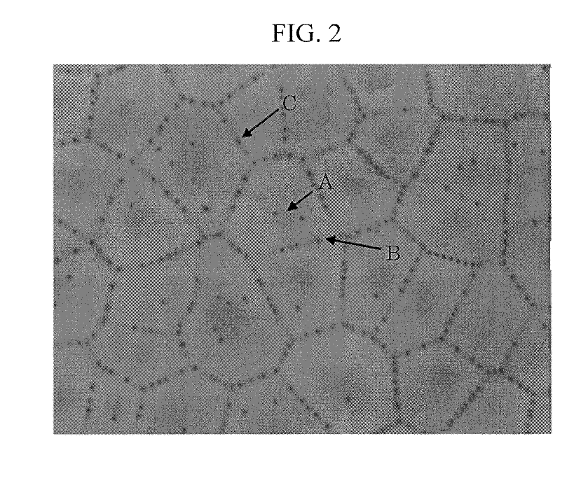

FIG. 2 is a microscopic image showing the surface of the polysilicon film formed by the aforementioned method. In FIG. 2, A represents the grain internal region, B represents the grain boundary, and C represents the recess portion remaining after the remaining metal catalyst has been removed.

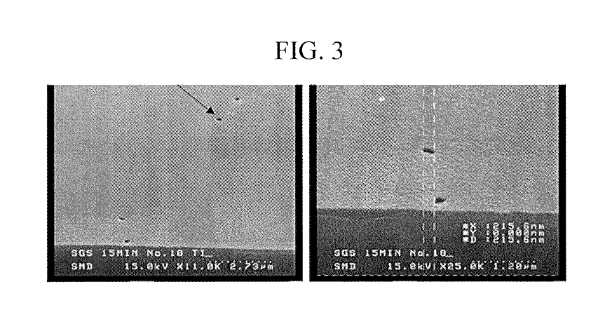

FIG. 3 is a scanning electron microscopic image showing an enlarged surface of a grain boundary shown in FIG. 2.

Referring to FIG. 3, it can be confirmed that the metal catalyst formerly remaining on the grain boundary has been removed due to treatment by the aforementioned etchant, and that the recess portion, corresponding to the previous position of the metal catalyst, is formed at positions from which the metal catalyst has been removed. In the left image of FIG. 3, the arrow indicates the recess portion.

As described above, according to the method of forming the polysilicon film 130 according to the present exemplary embodiment, the metal catalyst 50 remaining on the grain boundary 132 after crystallization of the amorphous silicon film 120 may be effectively removed. Therefore, in the thin film transistor where the polysilicon film 130 is used as the active layer, the leakage current is reduced or does not occur because the metal catalyst acting as defects is not present. As a result, an electric characteristic thereof may be improved.

Subsequently, the thin film transistor where the polysilicon film 130 formed by the aforementioned method is used as the active layer will be described.

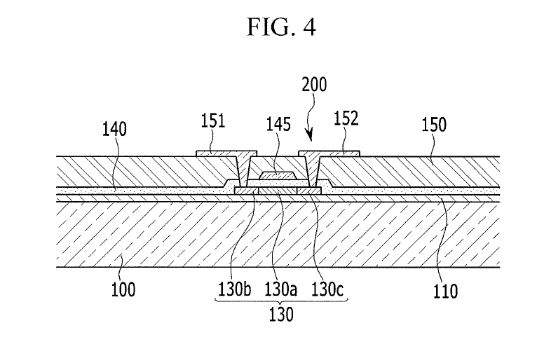

FIG. 4 is a cross-sectional view showing a thin film transistor according to the exemplary embodiment.

Referring to FIG. 4, the buffer layer 110 is formed on the substrate 100, and the polysilicon film 130 is formed on the buffer layer 110. The polysilicon film 130 is crystallized by using the metal catalyst according to the aforementioned method, such that the metal catalyst does not remain on the grain boundary, but instead, is removed by the aforementioned treatment of the etchant.

The polysilicon film 130 is patterned in a predetermined shape to be used as the active layer. The polysilicon film 130 includes a channel region 130a, a source region 130b, and a drain region 130c. A p-type impurity or an n-type impurity may be doped in the source region 130b and the drain region 130c.

A gate insulating layer 140 is formed on the buffer layer 110 while covering the polysilicon film 130. A gate electrode 145 is formed on the gate insulating layer 140 corresponding to a channel region 130a. The gate electrode 145 may be a same material as the polysilicon film 130. The gate electrode 145 acts as a blocking mask so that an impurity is not doped in the channel region 130a when the p-type impurity or the n-type impurity is doped.

An interlayer insulating layer 150 is formed on the gate insulating layer 140 while covering the gate electrode 145. A contact hole through which the source region 130b and the drain region 130c are exposed is formed in the interlayer insulating layer 150 and the gate insulating layer 140. A source electrode 151, connected through the contact hole to the source region 130b, and a drain electrode 152, connected through the contact hole to the drain region 130c, are formed on the interlayer insulating layer 150.

Since the aforementioned thin film transistor 200 uses the polysilicon film 130 from which the metal catalyst is removed as the active layer, defects trapping the carrier in the active layer may not be present. Therefore, in the thin film transistor 200 according to the present exemplary embodiment, the leakage current is reduced or does not occur. Accordingly, it is possible to reduce or prevent a phenomenon where the threshold voltage is increased.

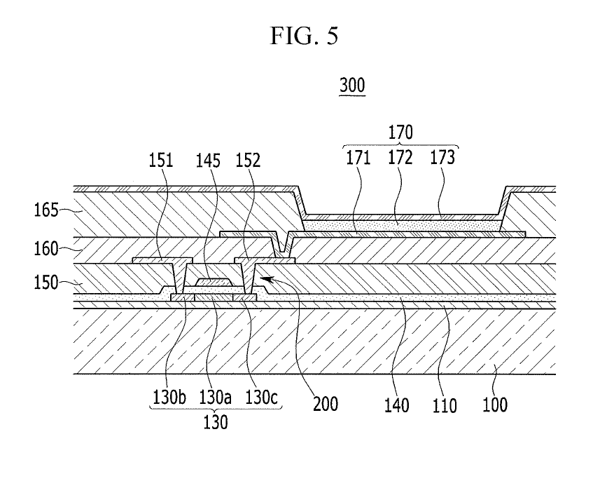

FIG. 5 is a cross-sectional view showing the display device using the aforementioned thin film transistor. FIG. 5 shows an organic light emitting diode (OLED) display as an example of the display device.

An organic light emitting diode (OLED) display 300 is connected to a plurality of signal lines, and includes a plurality of pixels arranged in an approximately matrix form. FIG. 5 shows one pixel of a plurality of pixels, and each pixel includes a plurality of thin film transistors, but for the convenience of description, only one thin film transistor 200 is shown herein.

Referring to FIG. 5, the buffer layer 110 is formed on the substrate 100, and the polysilicon film 130 is formed on the buffer layer 110. The polysilicon film 130 is crystallized by using the metal catalyst according to the aforementioned method, and the metal catalyst may not remain on the grain boundary by the aforementioned treatment of the etchant.

The polysilicon film 130 is patterned in a predetermined shape to be used as the active layer. The polysilicon film 130 includes a channel region 130a, a source region 130b, and a drain region 130c. The p-type impurity or the n-type impurity may be doped in the source region 130b and the drain region 130c.

The gate insulating layer 140 is formed on the buffer layer 110 while covering the polysilicon film 130. The gate electrode 145 is formed on the gate insulating layer 140 corresponding to the channel region 130a. In addition, the interlayer insulating layer 150 is formed on the gate insulating layer 140 while covering the gate electrode 145. The contact hole through which the source region 130b and the drain region 130c are exposed is formed in the interlayer insulating layer 150 and the gate insulating layer 140.

The source electrode 151 connected through the contact hole to the source region 130b and the drain electrode 152 connected through the contact hole to the drain region 130c are formed on the interlayer insulating layer 150. A planarization layer 160 is formed on the interlayer insulating layer 150 while covering the source electrode 151 and the drain electrode 152, and the contact hole through which the drain electrode 152 is exposed is formed in the planarization layer 160.

The pixel electrode 171 connected through the contact hole to the drain electrode 152 is formed on the planarization layer 160, and a pixel definition film 165 is formed on the planarization layer 160 while covering the pixel electrode 171. An opening through a portion of the pixel electrode 171 is exposed is formed in the pixel definition film 165.

An organic emission layer 172 is formed in the opening of the pixel definition film 165, and a common electrode 173 is formed on the entire pixel definition film 165 while covering the organic emission layer 172. Any one of the pixel electrode 171 and the common electrode 173 may act as an electron injection electrode (cathode), and the other one may act as a hole injection electrode (anode).

The organic emission layer 172 is formed of an organic material or a mixture of the organic material and an inorganic material emitting light of any one color of red, green, and blue. A subsidiary layer for improving the luminous efficiency of the organic emission layer 172 may be formed on lower and upper portions of the organic emission layer 172. The subsidiary layer may be at least one of a hole injection layer HIL, a hole transport layer HTL, an electron injection layer EIL, and an electron transport layer ETL.

Any one of the pixel electrode 171 and the common electrode 173 may be formed of the transparent conductive layer, and the other one may be formed of a reflective conductive layer. Light emitted from the organic emission layer 172 is reflected on the reflective conductive layer, transmitted through the transparent conductive layer, and emitted to the outside of the display device. The pixel electrode 171, the organic emission layer 172, and the common electrode 173 constitute the organic light emitting element 170.

In the above, the organic light emitting diode (OLED) display is described. In other implementations, the display device according to the present exemplary embodiment may be a liquid crystal display (LCD). In this case, the liquid crystal display (LCD) includes a liquid crystal layer (not shown), and may be formed to have various structures known to the person with ordinary skill in the art.

By way of summation and review, examples of a method of crystallizing an amorphous silicon film to form a polysilicon film include a solid phase crystallization method, an excimer laser crystallization method, a metal inducing crystallization method using a metal catalyst, a metal inducing lateral surface crystallization method, and the like.

Among the aforementioned methods, the crystallization method using the metal catalyst may shorten a crystallization process time and may be carried out at relatively low temperatures, as compared to the solid phase crystallization method. Further, the crystallization method using the metal catalyst is advantageous with regard to a process of manufacturing a large display device as compared to the crystallization method using a laser.

However, in the crystallization method using the metal catalyst, the metal catalyst may remain on a grain boundary after crystallization. The remaining metal catalyst may act as a defect to trap carriers, causing an occurrence of a leakage current and an increase in a threshold voltage in a thin film transistor including the polysilicon film.

In contrast, embodiments provide a method of forming a polysilicon film that may reduce the possibility of and/or prevent an effect caused by a metal catalyst so that a metal catalyst does not remain after crystallization. According to embodiments, it may be possible to effectively remove a metal catalyst remaining on a grain boundary after crystallization of an amorphous silicon film. Therefore, in a thin film transistor where a polysilicon film is used as an active layer, a leakage current may not occur based on a metal catalyst acting as a defect, since the metal catalyst may not be present. As a result, an electric characteristic may be improved. A thin film transistor and a display device including the polysilicon film may be manufactured by the method.

While this disclosure has been described in connection with what is presently considered to be practical exemplary embodiments, it is to be understood that the disclosed embodiments are not limiting, but, on the contrary, are intended to cover various modifications and equivalent arrangements included within the spirit and scope of the appended claims.

What is claimed is:

1. A method of forming a polysilicon film, the method comprising:
forming an amorphous silicon film on a substrate;
adsorbing a metal catalyst onto the amorphous silicon film;
crystallizing the amorphous silicon film through a heat treatment process to form a polysilicon film that includes a grain internal region and a grain boundary where the metal catalyst remains;
providing an etchant having different oxidation selectivities with respect to the grain internal region and the grain boundary; and
etching a surface of the polysilicon film by the etchant to remove the metal catalyst remaining on the grain boundary.

2. The method of forming a polysilicon film as claimed in claim 1, wherein:
the metal catalyst includes nickel, and
the nickel forms nickel-silicide to act as a seed to perform crystallization during the heat treatment process.

3. The method of forming a polysilicon film as claimed in claim 1, wherein the etchant includes an oxidizing agent having a higher oxidizing speed with respect to the grain boundary than with respect to the grain internal region.

4. The method of forming a polysilicon film as claimed in claim 3, wherein the etchant includes potassium dichromate as the oxidizing agent and hydrofluoric acid as an agent to remove silicon oxide.

5. The method of forming a polysilicon film as claimed in claim 3, wherein an etching thickness of the grain boundary is greater than an etching thickness of the grain internal region in the polysilicon film.

6. The method of forming a polysilicon film as claimed in claim 5, wherein etching the surface of the polysilicon film by the etchant to remove the metal catalyst remaining on the grain boundary forms a recess portion that remains on a surface of the grain boundary after the metal catalyst is removed.

7. A thin film transistor, comprising:
a polysilicon film formed according to the method as claimed in claim 1;
a gate insulating layer on the polysilicon film;
a gate electrode on the gate insulating layer, the gate electrode overlapping the polysilicon film; and
a source electrode and a drain electrode spaced apart from the gate electrode and electrically connected to the polysilicon film.

8. A thin film transistor, comprising:
a polysilicon film including a grain internal region and a grain boundary, the grain boundary including a recess portion corresponding to a position from which a metal catalyst was removed;
a gate insulating layer on the polysilicon film;
a gate electrode on the gate insulating layer and overlapping the polysilicon film; and
a source electrode and a drain electrode spaced apart from the gate electrode and electrically connected to the polysilicon film.

9. A display device, comprising:
a polysilicon film formed according to the method as claimed in claim 1;
a gate insulating layer on the polysilicon film;
a gate electrode on the gate insulating layer and overlapping the polysilicon film; and
a source electrode and a drain electrode spaced apart from the gate electrode and electrically connected to the polysilicon film.

10. The display device as claimed in claim 9, further comprising:
a pixel electrode electrically connected to the drain electrode;
a common electrode facing the pixel electrode; and
an organic emission layer between the pixel electrode and the common electrode.

11. A display device, comprising:
a polysilicon film including a grain internal region and a grain boundary, the grain boundary including a recess portion corresponding to a position from which a metal catalyst was removed;
a gate insulating layer on the polysilicon film;
a gate electrode on the gate insulating layer and overlapping the polysilicon film; and
a source electrode and a drain electrode spaced apart from the gate electrode and electrically connected to the polysilicon film.

12. The display device as claimed in claim 11, further comprising:
a pixel electrode electrically connected to the drain electrode;
a common electrode facing the pixel electrode; and
an organic emission layer between the pixel electrode and the common electrode.
